(19) United States
(12) Patent Application Publication
(10) Pub. No.: US 2008/0043134 A1
(43) Pub. Date: Feb. 21, 2008

(54) IMAGING DEVICE

(75) Inventors: Eric CHRISTISON, Edinburgh (GB); Ewan Findlay, Falkirk (GB)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics (Research & Development) Limited, Marlow (GB)

(21) Appl. No.: 11/840,316

(22) Filed: Aug. 17, 2007

(30) Foreign Application Priority Data
Aug. 17, 2006 (EP) 06270082 . 2

(51) Int. Cl. H04N 5/225

(52) U.S. Cl. 348/342

(57) ABSTRACT

The imaging device includes an image sensor, a lens member adapted to focus external radiation towards the image sensor and a heat shield to inhibit thermal damage to the lens member. The heat shield may include an optical filter between the lens member and the external radiation.

### FIELD OF THE INVENTION

The present invention relates to the field of imaging devices. In particular, but not exclusively, the invention relates to an imaging device which includes a solid state image sensor, and a method of manufacturing the imaging device.

### BACKGROUND OF THE INVENTION

Imaging devices including solid state image sensors are being incorporated into low cost cameras and other handheld devices, such as mobile cellular telephones and personal digital assistants. These handheld devices may have a main function which is unrelated to capturing images. It is desirable to minimize the cost of the imaging devices.

Image sensors require a focussing lens as part of the assembly so that a representation of a subject may be reproduced. The imaging assembly typically also incorporates other components such as additional lens elements, an aperture and an infra-red (IR) filter. The IR filter is present to prevent infrared radiation impinging on the image sensor. Typically, the IR filter is provided at a rear surface of the lens, between the lens and sensor.

Conventionally, prior art imaging assemblies mount individual components in a support structure commonly referred to as a “barrel”. The lenses and barrel are usually made from low cost materials such as plastic. Generally, prior-art imaging assemblies of this type are intentionally low cost. However, they can suffer from the problem that they do not survive elevated temperatures.

It is beneficial for an imaging device to be able to withstand elevated temperatures. One reason for this is that the solid state image sensors are often subjected to a re-flow solder process. The re-flow solder process requires that the image sensor is passed through a re-flow oven which melts solder deposits to electrically connect various elements. In a fixing operation, prior to passing the image sensor through a reflow oven, components of the image sensor are fixed in place. Because the imaging assembly cannot tolerate the temperature of the reflow oven, it is fixed in place in a separate fixing operation. It would be advantageous if only one fixing operation was needed for all components.

Typically, the components associated with prior art “barrel” imaging assemblies have optical properties that are modified by elevated temperature and therefore are not suitable for a re-flow solder process. Often, components are attached to a substrate via a socket or flexible circuit so that they do not have to pass through the re-flow solder process. However, the inclusion of sockets or flexible circuits adds to the cost and size of the assembly. Alternatively, glass rather than plastic lenses may be used. However, such lenses can still be affected by elevated temperatures. They are also more expensive and known to be less accurate.

### SUMMARY OF THE INVENTION

According to a first aspect of the present invention there is provided an imaging device comprising: an image sensor; a lens member adapted to focus external radiation towards the image sensor; and a heat shield or shielding means adapted to inhibit thermal damage to the lens member. The heat shield or shielding means includes an optical filter between the lens member and the external radiation.

The optical filter may comprise an IR filter, such as one or more coatings which inhibit the transmission of infrared electromagnetic radiation. The heat shield or shielding means may further comprise a housing for at least partially encapsulating the lens member. The housing may be formed from an opaque material and/or a polymer material. The heat shield or shielding means may further comprise a base member coupled to the housing for at least partially encapsulating the lens member.

The image sensor may comprise a solid state image sensor, such as a CMOS image sensor or a CCD image sensor. The base member may comprise a substrate. Preferably the lens member is formed from a material having a high melting temperature to provide co-operating heat shielding means. The melting temperature of the material may be greater than 200° C., most preferably greater than 250° C. Preferably the lens member is at least partially formed from a polymer material and/or a modified polycarbonate, such as Sunex™. Alternatively, the lens member may be at least partially formed from a polyetherimide, such as Ultem™.

Preferably the imaging device includes an aperture. The imaging device may include an opaque coating and the aperture may be a passage in the opaque coating. Preferably the opaque coating is provided at the optical filter.

According to a second aspect of the present invention there is provided an imaging device comprising: an image sensor; a lens member adapted to focus external radiation towards the image sensor; and a heat shield or shielding means adapted to inhibit thermal damage to the lens member. The lens member is formed from a material having a high melting temperature to provide the heat shield or shielding means.

Preferably the melting temperature of the material is greater than 200° C., most preferably greater than 250° C. The lens member may be at least partially formed from a polymer material. The imaging device may include co-operating heat shielding means, such as an optical filter, e.g. an IR filter, between the lens member and the external radiation. The heat shield or shielding means may further comprise a housing for at least partially encapsulating the lens member, and may include a base member coupled to the housing for at least partially encapsulating the lens member.

According to a third aspect of the present invention there is provided a method of manufacturing an imaging device, the device comprising an image sensor and a lens member adapted to focus external radiation towards the image sensor, the method comprising: interposing an optical filter between the lens member and the external radiation to inhibit thermal damage to the lens member.

The optical filter may comprise an IR filter. The method further comprises at least partially encapsulating the lens member within a housing, and may include coupling a base member to the housing for at least partially encapsulating the lens member. The method may include forming the lens member from a material having a high melting temperature to further inhibit thermal damage to the lens member. Preferably the melting temperature of the material is greater than 200° C., most preferably greater than 250° C. The lens member may be at least partially formed from a polymer material. The method may include subjecting the imaging device to a re-flow solder process.

According to a fourth aspect of the present invention there is provided a method of manufacturing an imaging device, the device comprising an image sensor and a lens member adapted to focus external radiation towards the image sensor, the method comprising: forming the lens member from a material having a high melting temperature to inhibit thermal damage to the lens member.

Preferably the melting temperature of the material is greater than 200° C., most preferably greater than 250° C. The lens member may be at least partially formed from a polymer material. The method may include interposing an optical filter between the lens member and the external radiation to further inhibit thermal damage to the lens member. The optical filter may comprise an IR filter.

The method may further comprise at least partially encapsulating the lens member within a housing, and may include coupling a base member to the housing for at least partially encapsulating the lens member. The method may include subjecting the imaging device to a re-flow solder process.

### BRIEF DESCRIPTION OF THE DRAWINGS

An embodiment of the present invention will now be described, by way of example only, with reference to the accompanying drawings, in which:

FIG. 1 is a plan view of an imaging device in accordance with features of the present invention;

FIG. 2 is a sectional side view of the imaging device of FIG. 1;

FIG. 3 is a perspective view of the imaging device of FIG. 1; and

FIG. 4 is a graph of the temperature with respect to time during a typical re-flow solder process.

### DETAILED DESCRIPTION OF THE PREFERRED EMBODIMENTS

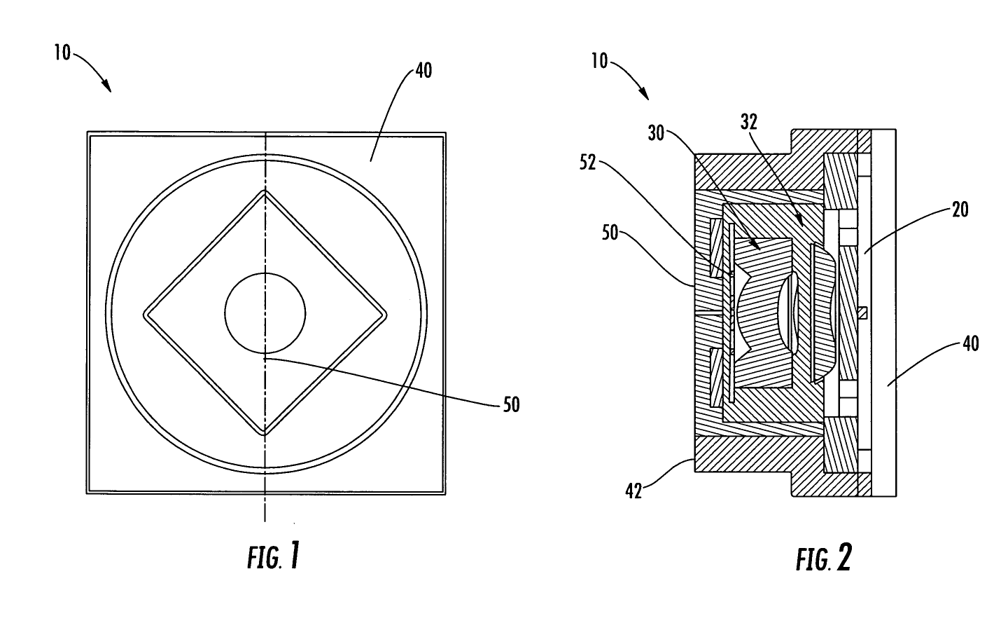

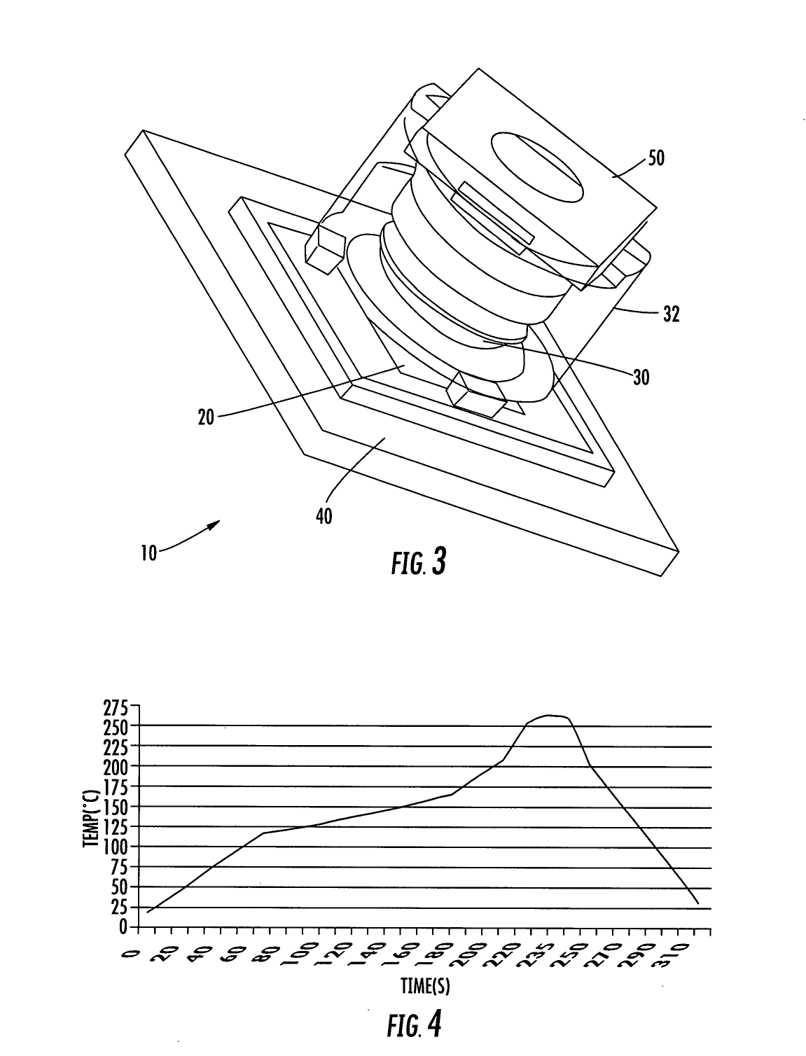

FIGS. 1 to 3 show an imaging device 10 which comprises a solid state CMOS image sensor 20 and a lens 30 adapted to focus external light towards the image sensor 20. The image sensor 20 is provided on a base member or substrate 40.

An optical filter in the form of an IR filter 50 is provided in an optical path between the lens 30 and the external light. Also, an aperture 52 is provided at the lens 30. The IR filter 50 provides a heat shield or shielding means which inhibits thermal damage to the lens 30, in particular during the manufacturing process. The IR filter 50 may be formed by applying to a glass plate a number of coatings of a material which inhibits the transmission of infrared electromagnetic radiation.

The lens 30 is provided in a barrel 32 and the barrel 32 is partial y encapsulated in an opaque plastic housing 42 which is fixed to the substrate 40. The housing 42 and substrate 40 also provide heat shielding to the lens 30 as the lens 30 is only exposed to external radiation via the infrared filter 50.

The lens 30 may be formed from a polymer material having a relatively high melting temperature. This melting temperature is greater than 200° C., and preferably greater than 250° C. One suitable material is a modified polycarbonate, such as Sunex™.

FIG. 4 shows a graph of temperature against time during a typical re-flow solder process. The heating rate is designed to be no greater than 3° C., and the cooling rate no greater than 6° C. The peak temperature during the process is about 260° C. However, the time during which the imaging device 10 is subject to temperatures above 200° C. is less than 90 seconds, and preferably less than 70 seconds. Furthermore, the time during which the imaging device 10 is subject to temperatures above 250° C. is less than 30 seconds, and preferably less than 20 seconds.

The presence and location of the IR filter 50 is sufficient to provide a heat shield or shielding means which substantially prevents thermal damage to the lens 30 at high temperatures during the manufacturing process. The relatively high melting temperature of the lens material co-operates with the IR filter 50 to provide additional heat shielding.

The imaging device 10 of the invention can therefore be subject to the high temperatures of the typical manufacturing process. This eliminates the need for additional sockets or flexible circuits, as well as the additional assembly steps involved with these additional components.

Various modifications and improvements can be made without departing from the scope of the present invention.

1-32. (canceled)

33. An imaging device comprising:
an image sensor;
a lens member to focus external radiation towards the image sensor; and
a heat shield to inhibit thermal damage to the lens member and comprising an optical filter positioned between the lens member and the external radiation.

34. An imaging device as claimed in claim 33, wherein the optical filter comprises an infrared (IR) filter.

35. An imaging device as claimed in claim 33, wherein the heat shield further comprises a housing for at least partially encapsulating the lens member.

36. An imaging device as claimed in claim 33, wherein the heat shield further comprises a base member for at least partially encapsulating the lens member.

37. An imaging device as claimed in claim 36, wherein the base member comprises a substrate.

38. An imaging device as claimed in claim 33, wherein the lens member comprises a relatively high melting temperature material to define a co-operating heat shield.

39. An imaging device as claimed in claim 38, wherein the melting temperature of the material is greater than 200° C.

40. An imaging device as claimed in claim 39, wherein the melting temperature of the material is greater than 250° C.

41. An imaging device as claimed in claim 33, wherein the lens member comprises a polymer material.

42. An imaging device as claimed in claim 33, wherein the image sensor comprises a solid state image sensor.

43. An imaging device as claimed in claim 42, wherein the image sensor comprises a CMOS image sensor.

44. An imaging device comprising:
an image sensor;
a lens member to focus external radiation towards the image sensor; and
a heat shield to inhibit thermal damage to the lens member and comprising a material having a high melting temperature to define the lens member.

45. An imaging device as claimed in claim 44, wherein the melting temperature of the material is greater than 200° C.

46. An imaging device as claimed in claim 45, wherein the melting temperature of the material is greater than 250° C.

47. An imaging device as claimed in claim 45, including a co-operating heat shield comprising an optical filter positioned between the lens member and the external radiation.

48. An imaging device as claimed in claim 47, wherein the optical filter comprises an IR filter.

49. An electronic device comprising:
an imaging device including
an image sensor,
a lens member to focus external radiation towards the image sensor, and
a heat shield to inhibit thermal damage to the lens member and comprising an optical filter positioned between the lens member and the external radiation.

50. An electronic device as claimed in claim 49, wherein the electronic device defines an optical pointing device.

51. An electronic device as claimed in claim 50, wherein the optical pointing device defines an optical mouse.

52. An electronic device as claimed in claim 49, wherein the electronic device defines a mobile device.

53. An electronic device as claimed in claim 52, wherein the mobile device comprises a mobile cellular telephone.

54. An electronic device as claimed in claim 52, wherein the mobile device comprises a camera.

55. A method of manufacturing an imaging device, the method comprising:
providing an image sensor;
providing a lens member to focus external radiation towards the image sensor; and
positioning an optical filter between the lens member and the external radiation to inhibit thermal damage to the lens member.

56. A method as claimed in claim 55, wherein the optical filter comprises an IR filter.

57. A method as claimed in claim 55, further comprising forming the lens member from a material having a high melting temperature to further inhibit thermal damage to the lens member.

58. A method as claimed in claim 55, further comprising subjecting the imaging device to a re-flow solder process.

59. A method of manufacturing an imaging device, the method comprising:
providing an image sensor;
providing a lens member to focus external radiation towards the image sensor and comprising forming the lens member from a material having a high melting temperature to inhibit thermal damage to the lens member.

60. A method as claimed in claim 59, wherein the melting temperature of the material is greater than 200° C.

61. A method as claimed in claim 60, wherein the melting temperature of the material is greater than 250° C.

62. A method as claimed in claim 59, wherein the lens member is at least partially formed from a polymer material.

63. A method as claimed in claim 59, further comprising positioning an optical filter between the lens member and the external radiation to further inhibit thermal damage to the lens member.

64. A method as claimed in claim 63, wherein the optical filter comprises an IR filter.

65. A method as claimed in claim 59, further comprising subjecting the imaging device to a re-flow solder process.
